(19) United States
(12) Patent Application Publication
(10) Pub. No.: US 2014/0124359 A1
(43) Pub. Date: May 8, 2014

(54) New Magnet Design Which Improves Erosion Profile for PVD Systems

(71) Applicant: INTERMOLECULAR, INC., San Jose, CA (US)

(72) Inventors: ShouQian Shao, Fremont, CA (US); Kent Riley Child, Dublin, CA (US); Danny Wang, Saratoga, CA (US); Xuena Zhang, San Jose, CA (US)

(73) Assignee: INTERMOLECULAR, INC., San Jose, CA (US)

(21) Appl. No.: 13/667,856

(22) Filed: Nov. 2, 2012

(51) Int. Cl. C23C 14/35

(52) U.S. Cl. 204/192.13; 204/298.15; 204/298.12

(57) ABSTRACT

Methods and apparatuses for performing combinatorial processing are disclosed. Methods include introducing a substrate into a processing chamber. The processing chamber includes a sputter assembly disposed over the substrate. The sputter assembly includes a rotatable n-fold, symmetric-shaped magnetron and a sputter target. The methods include depositing a first film on the surface of a first site-isolated region of the substrate. The methods further include depositing a second film on the surface of a second site-isolated region of the substrate. Furthermore, methods include evaluating results of the first and second films.

### FIELD OF INVENTION

The present disclosure relates to physical vapor deposition processes for depositing thin films on substrates.

### BACKGROUND OF THE INVENTION

Conventional physical vapor deposition (sputter) systems include magnetrons therein. Typically, magnetron systems include permanent magnets to provide strong magnetic fields around a sputter target. The magnetic fields created by the magnetron systems confine high-density plasma close to the sputter target. In some systems, magnetic fields can form a closed-loop annular path around a sputter target. The closed-loop annular path serves as an electron trap to direct the electrons ejected from the sputter target into a helical path thereby increasing the probability of sputtering gas ionization within the confinement zone.

An inert gas, particularly argon, is usually employed as a sputtering gas because it tends not to react with the target material or combine with any process gas, and because it produces higher sputtering and deposition rates. In PVD processes, positively charged argon ions are accelerated towards a negatively biased target (cathode), resulting in material being sputtered from the target surface onto a substrate.

In time, a conventional sputter target will become thinner as erosion advances and the magnetic fields on the eroded areas become stronger. A stronger magnetic field accelerates erosion creating deep, narrow channels on the surface of the substrate. The result is a short sputter target life and non-uniform films being deposited on the substrate. What is needed is a magnetron assembly which improves the erosion profile of sputter targets thereby increasing their lifetime.

The present invention addresses such a need.

### SUMMARY OF THE INVENTION

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Methods and apparatuses for performing combinatorial processing are disclosed. Methods include introducing a substrate into a processing chamber. The processing chamber includes a sputter assembly disposed over the substrate. The sputter assembly includes a rotatable n-fold, symmetric-shaped magnetron and a sputter target. The methods include depositing a first film on the surface of a first site-isolated region of the substrate. The methods further include depositing a second film on the surface of a second site-isolated region of the substrate. Furthermore, methods include evaluating results of the first and second films.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale. The techniques of the present disclosure can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 is a simplified schematic diagram illustrating a sputter chamber configured to perform combinatorial processing and full substrate processing.

FIG. 5 is a top view of a magnetron for a sputter target assembly.

FIG. 6 is a top view of a magnetron.

FIG. 7A is a top view of a sputter target assembly.

FIG. 7B is a top view of a magnetron having achieved rotational symmetry.

FIG. 7C is a side view of a sputter target assembly.

FIG. 8 illustrates one example of a pattern of site-isolated regions.

FIGS. 9A-9D illustrates an exemplary deposition sequence for forming multilayer film stacks in a combinatorial fashion.

FIGS. 10A-10D illustrates an exemplary deposition sequence for forming multilayer film stacks in a combinatorial fashion.

FIGS. 11A-11D illustrates an exemplary deposition sequence for forming multilayer film stacks in a combinatorial fashion.

FIG. 12 shows a chart with the erosion profiles of conventional sputter targets and sputter target system embodiments of the present disclosure.

### DETAILED DESCRIPTION

Methods and apparatuses for performing combinatorial processing are disclosed. Methods include introducing a substrate into a processing chamber. The processing chamber includes a sputter assembly disposed over the substrate. The sputter assembly includes a rotatable n-fold, symmetric-shaped magnetron and a sputter target. The methods include depositing a first film on the surface of a first site-isolated region of the substrate. The methods further include depositing a second film on the surface of a second site-isolated region of the substrate. Furthermore, methods include evaluating results of the first and second films.

Before the present disclosure is described in detail, it is to be understood that unless otherwise indicated this disclosure is not limited to specific layer compositions or surface treatments. It is also to be understood that the terminology used herein is for the purpose of describing particular embodiments only and is not intended to limit the scope of the present disclosure.

It must be noted that as used herein and in the claims, the singular forms “a,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the disclosure. The upper and lower limits of these smaller ranges may independently be included in the smaller ranges, and are also encompassed within the disclosure, subject to any specifically excluded limit in the stated range. Where the stated range includes one or both of the limits, ranges excluding either or both of those included limits are also included in the disclosure. The term “about” generally refers to ±10% of a stated value.

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within±10%, within±5%, within±2%, within±1%, or within 35 0.1% of the target conditions. Where one region is processed at a time, adjacent regions are generally protected from any exposure that would alter the substrate surface in a measurable way.

The term “site-isolated region” is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, coated silicon, other semiconductor materials, glass, polymers, metal foils, etc. The term “substrate” or “wafer” may be used interchangeably herein. Semiconductor wafer shapes and sizes may vary and include commonly used round wafers of 2″, 4″, 200 mm, or 300 mm in diameter.

It is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for HPC™ processing are described in U.S. Pat. No. 7,544,574 filed on Feb. 10, 2006; U.S. Pat. No. 7,824,935 filed on Jul. 2, 2008; U.S. Pat. No. 7,871,928 filed on May 4, 2009; U.S. Pat. No. 7,902,063 filed on Feb. 10, 2006; and U.S. Pat. No. 7,947,531 filed on Aug. 28, 2009 which are all herein incorporated by reference. Systems and methods for HPC™ processing are further described in U.S. patent application Ser. No. 11/352,077 filed on Feb. 10, 2006, claiming priority from Oct. 15, 2005; U.S. patent application Ser. No. 11/419,174 filed on May 18, 2006, claiming priority from Oct. 15, 2005; U.S. patent application Sr. No. 11/674,132 filed on Feb. 12, 2007, claiming priority from Oct. 15, 2005; U.S. patent application Ser. No. 11/674,137 filed on Feb. 12, 2007; and U.S. patent application Ser. No. 13/302,730 filed on Nov. 22, 2011 claiming priority from Oct. 15, 2005 which are all herein incorporated by reference for all purposes.

HPC™ processing techniques have been successfully adapted to wet chemical processing such as etching, texturing, polishing, cleaning, etc. HPC™ processing techniques have also been successfully adapted to deposition processes such as physical vapor deposition (PVD) (i.e. sputtering), atomic layer deposition (ALD), and chemical vapor deposition (CVD).

HPC™ processing techniques have been adapted to the development and investigation of absorber layers and buffer layers for TFPV solar cells as described in U.S. patent application Ser. No. 13/236,430 filed on Sep. 19, 2011, entitled “COMBINATORIAL METHODS FOR DEVELOPING SUPERSTRATE THIN FILM SOLAR CELLS” and is incorporated herein by reference for all purposes.

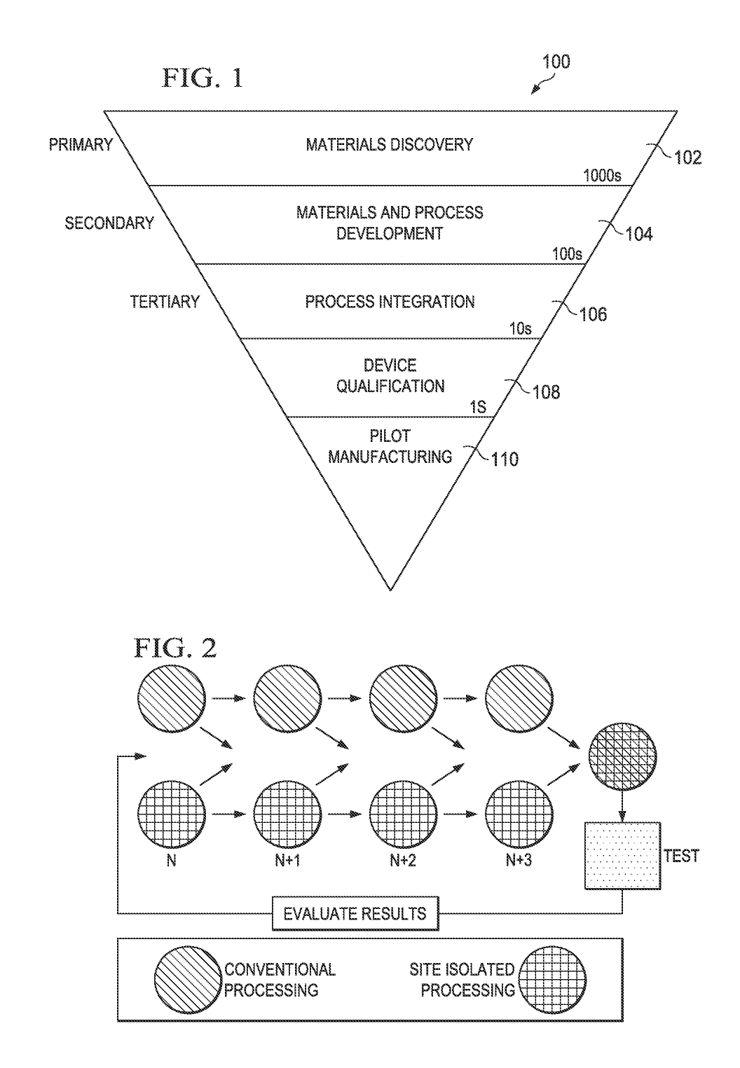

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a material's discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e. microscopes).

The materials and process development stage, 104, may evaluate hundreds of materials (i.e. a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from HPC™ techniques described in U.S. patent application Ser. No. 11/674,137 filed on Feb. 12, 2007 which is hereby incorporated for reference for all purposes. Portions of the '137 application have been reproduced below to enhance the understanding of the present disclosure.

While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete site-isolated region. Furthermore, while different materials or unit processes may be used for corresponding layers or steps in the formation of a structure in different site-isolated regions of the substrate during the combinatorial processing, the application of each layer or use of a given unit process is substantially consistent or uniform throughout the different site-isolated regions in which it is intentionally applied. Thus, the processing is uniform within a site-isolated region (inter-region uniformity) and between site-isolated regions (intra-region uniformity), as desired. It should be noted that the process can be varied between site-isolated regions, for example, where a thickness of a layer is varied or a material may be varied between the site-isolated regions, etc., as desired by the design of the experiment.

The result is a series of site-isolated regions on the substrate that contain structures or unit process sequences that have been uniformly applied within that site-isolated region and, as applicable, across different site-isolated regions. This process uniformity allows comparison of the properties within and across the different site-isolated regions such that the variations in test results are due to the varied parameter (e.g., materials, unit processes, unit process parameters, hardware details, or process sequences) and not the lack of process uniformity. In the embodiments described herein, the positions of the discrete site-isolated regions on the substrate can be defined as needed, but are preferably systematized for ease of tooling and design of experimentation. In addition, the number, variants and location of structures within each site-isolated region are designed to enable valid statistical analysis of the test results within each site-isolated region and across site-isolated regions to be performed.

FIG. 2 is a simplified schematic diagram illustrating a general methodology for combinatorial process sequence integration that includes site isolated processing and/or conventional processing in accordance with some embodiments of the disclosure. In some embodiments, the substrate is initially processed using conventional process N. In some exemplary embodiments, the substrate is then processed using site isolated process N+1. During site isolated processing, an HPC™ module may be used, such as the HPC module described in U.S. patent application Ser. No. 11/352,077 filed on Feb. 10, 2006, which is incorporated herein by reference for all purposes. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different site-isolated regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from site-isolated region to site-isolated region on the substrate. Thus, for example, when exploring materials, a processing material delivered to a first and second site-isolated regions can be the same or different. If the processing material delivered to the first site-isolated region is the same as the processing material delivered to the second site-isolated region, this processing material can be offered to the first and second site-isolated regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used may be varied.

As mentioned above, within a site-isolated region, the process conditions are substantially uniform. That is, the embodiments described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the site-isolated regions. It should be appreciated that a site-isolated region may be adjacent to another region in some embodiments or the site-isolated regions may be isolated and, therefore, non-overlapping. When the site-isolated regions are adjacent, there may be a slight overlap wherein the materials or precise process interactions are not known, however, a portion of the site-isolated regions, normally at least 50% or more of the area, is uniform and all testing occurs within that site-isolated region. Further, the potential overlap is only allowed with material of processes that will not adversely affect the result of the tests. Both types of site-isolated regions are referred to herein as site-isolated regions or discrete site-isolated regions.

Substrates may be a conventional round 200 mm, 300 mm, or any other larger or smaller substrate/wafer size. In other embodiments, substrates may be square, rectangular, or other shape. One skilled in the art will appreciate that substrate may be a blanket substrate, a coupon (e.g., partial wafer), or even a patterned substrate having predefined site-isolated regions. In some embodiments, a substrate may have site-isolated regions defined through the processing described herein.

Software is provided to control the process parameters for each wafer for the combinatorial processing. The process parameters comprise selection of one or more source gases for the plasma generator, plasma filtering parameters, exposure time, substrate temperature, power, frequency, plasma generation method, substrate bias, pressure, gas flow, or combinations thereof.

Conventional systems using remote plasma sources were designed to treat the entire area of a substrate such as a 300 mm wafer. Combinatorial processing is difficult and expensive when the entire area of a substrate can only receive a single process variation. Embodiments of the present disclosure overcome this limitation by providing a remote plasma source, an associated substrate positioning system, and a site isolation system that allows a selected site-isolated region of a substrate to be processed while the remaining site-isolated regions of the substrate are protected from exposure to the plasma and reactive radical species unless or until such exposure is intended.

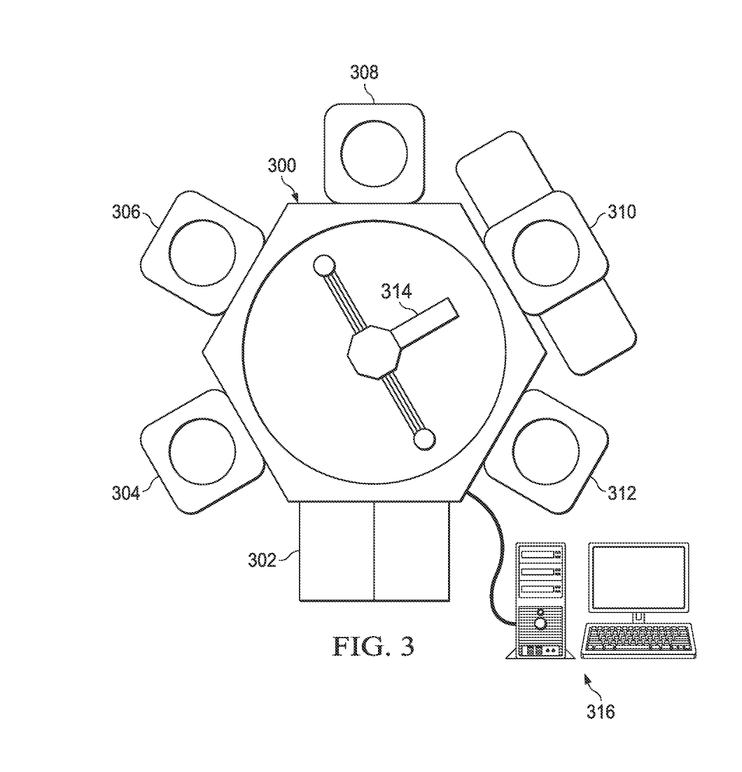

FIG. 3 is a simplified schematic diagram illustrating an integrated high productivity combinatorial (HPC) system in accordance with some embodiments of the disclosure. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. patent application Ser. Nos. 11/672,473 and 11/672,478, the entire disclosures of which are herein incorporated by reference. In a HPC system, a plurality of methods may be employed to deposit material upon a substrate employing combinatorial processes.

According to some embodiments, a method of combinatorial processing of a substrate is provided in which site-isolated sputter deposition and plasma etching are carried out in the same process chamber. The site-isolated sputter deposition may be site-isolated co-sputtering deposition. Cleaning, site-isolated sputter deposition and plasma etching may be carried out in the same process chamber. Cleaning, site-isolated sputter deposition and plasma etching, and full wafer sputter deposition may be carried out in the same process chamber.

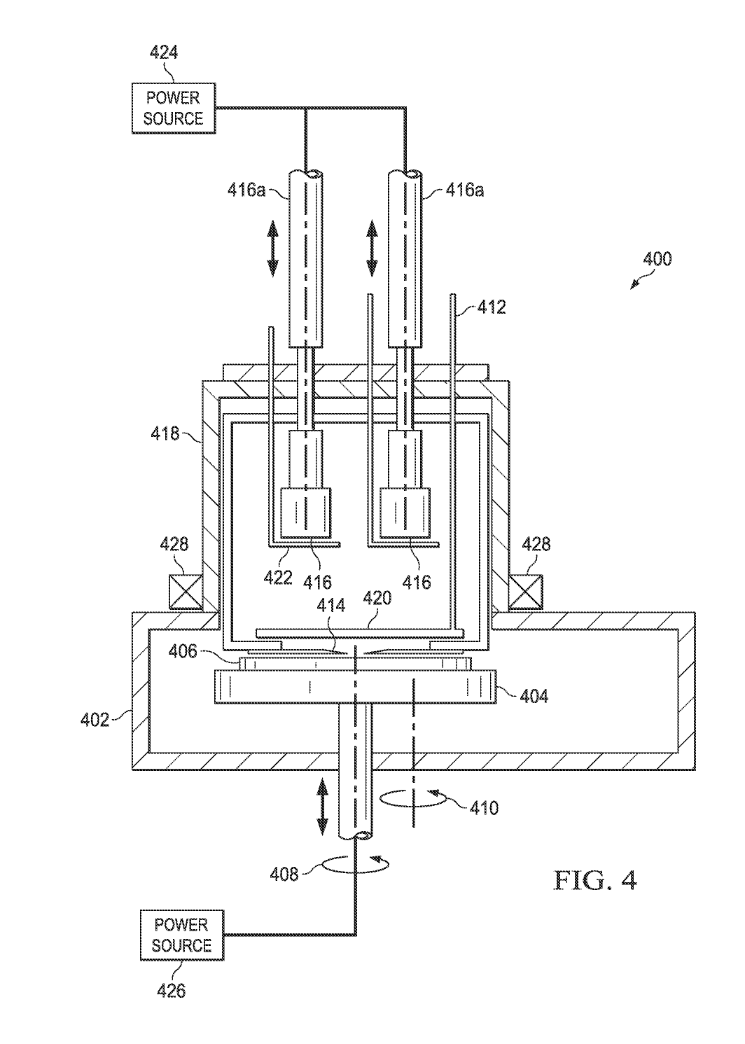

FIG. 4 is a simplified schematic diagram illustrating a sputter chamber configured to perform combinatorial processing and full substrate processing. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. In some embodiments, substrate support 404 is stationary and the central axis of the substrate support is aligned with masks utilized for processing a substrate as described below.

Power source 426 provides a bias power to substrate support 404 and substrate 406, and produces a negative bias voltage on substrate 406. In some embodiments power source 426 provides a radio frequency (RF) power sufficient to take advantage of the high metal ionization to improve step coverage of vias and trenches of patterned wafers. In some embodiments, the RF power supplied by power source 426 is pulsed and synchronized with the pulsed power from power source 424. Further details of the power sources and their operation may be found in U.S. patent application Ser. No. 13/281,316 entitled “High Metal Ionization Sputter Gun” filed on Oct. 25, 2011 with internal docket number (IM0281) and is herein incorporated by reference.

Substrate 406 may be a conventional round 200 mm, 300 mm, or any other larger or smaller substrate/wafer size. In some embodiments, substrate 406 may be a square, rectangular, or other shaped substrate. One skilled in the art will appreciate that substrate 406 may be a blanket substrate, a coupon (e.g., partial wafer), or even a patterned substrate having predefined site-isolated regions. In some embodiments, substrate 406 may have site-isolated regions defined through the processing described herein. The term site-isolated region is used herein to refer to a localized area on a substrate which is, was, or is intended to be used for processing or formation of a selected material. The site-isolated region can include one site-isolated region and/or a series of regular or periodic site-isolated regions predefined on the substrate. The site-isolated region may have any convenient shape, e.g., circular, rectangular, elliptical, wedge-shaped, etc. In the semiconductor field a site-isolated region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412, which defines a confinement site-isolated region over a radial portion of substrate 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process site-isolated regions of the substrate in some embodiments. In some embodiments, full wafer processing can be achieved by optimizing gun tilt angle and target-to-substrate spacing, and by using multiple process guns 416. Process kit shield 412 is capable of being moved in and out of chamber 400, i.e., the process kit shield is a replaceable insert. In some embodiments, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In some embodiments, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and plate 420 may extend with that opening to either completely cover the aperture or place one or more fixed apertures within that opening for processing the defined site-isolated regions. In some embodiments, the base of process kit shield is replaced by independently rotatable masks configured to access and expose a desired site-isolated region of substrate 406 as described below.

A gun shutter, 422 may be included. Gun shutter 422 functions to seal off a deposition gun when the deposition gun may not be used for the processing in some embodiments. For example, two process guns 416 are illustrated in FIG. 4. Process guns 416 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter 422 can be transitioned to isolate the lifted process guns from the processing area defined within process kit shield 412. In this manner, the process guns are isolated from certain processes when desired.

It should be appreciated that slide cover plate 422 may be integrated with the top of the process kit shield 412 to cover the opening as the process gun is lifted or individual cover plate 422 can be used for each target. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion 418 of chamber 400 of FIG. 4 includes sidewalls and a top plate which house process kit shield 412. Arm extensions 416a, which are fixed to process guns 416 may be attached to a suitable drive, e.g., lead screw, worm gear, etc., configured to vertically move process guns 416 toward or away from a top plate of top chamber portion 418. Arm extensions 416a may be pivotally affixed to process guns 416 to enable the process guns to tilt relative to a vertical axis. In some embodiments, process guns 416 tilt toward aperture 414 when performing combinatorial processing and tilt toward a periphery of the substrate being processed when performing full substrate processing. It should be appreciated that process guns 416 may tilt away from aperture 414 when performing combinatorial processing in some embodiments. In some embodiments, arm extensions 416a are attached to a bellows that allows for the vertical movement and tilting of process guns 416. Arm extensions 416a enable movement with four degrees of freedom in some embodiments. Where process kit shield 412 is utilized, the aperture openings are configured to accommodate the tilting of the process guns. The amount of tilting of the process guns may be dependent on the process being performed in some embodiments.

Power source 424 provides power for sputter guns 416 whereas power source 426 provides RF bias power to an electrostatic chuck to bias the substrate when necessary. It should be appreciated that power source 424 may output a direct current (DC) power supply or a radio frequency (RF) power supply.

Chamber 400 includes auxiliary magnet 428 disposed around an external periphery of the chamber. The auxiliary magnet 428 is located in a site-isolated region defined between the bottom surface of sputter guns 416 and a top surface of substrate 406. Magnet 428 may be either a permanent magnet or an electromagnet. It should be appreciated that magnet 428 is utilized to provide more uniform bombardment of argon ions and electrons to the substrate in some embodiments. In addition, auxiliary magnet may be disposed proximate to substrate support 404. Alternatively, auxiliary magnet may be integrated within substrate support 404.

Generally, a gas source supplies a sputtering working gas (or gases), such as argon, to a chamber through a mass flow controller. The gases may be admitted through the top of the chamber, as illustrated, or at its bottom, either with one or more inlet pipes penetrating the bottom of the shield or through the gap between the shield and the pedestal. A vacuum system maintains the chamber at a low pressure. Although the base pressure can be held to about 10⁻⁷ Torror even lower, the pressure of the working gas is typically maintained at between about 1 and 1000 mTorr. A computer-based controller controls the reactor including the DC power supply and the mass flow controllers.

When the argon is admitted into the chamber, the DC voltage between the target and the shield ignites the argon into a plasma, and the positively charged argon ions are attracted to the negatively charged target. The ions strike the target at a substantial energy and cause target atoms or atomic clusters to be sputtered from the target. Some of the target particles strike the wafer and are thereby deposited on it, thereby forming a film of the target material. In reactive sputtering of a metallic nitride, nitrogen is additionally admitted into the chamber, and it reacts with the sputtered metallic atoms to form a metallic nitride on the wafer.

To provide efficient sputtering, a magnetron is positioned in back of the target. Conventional magnetrons include magnets which create a magnetic field within the sputter chamber 400 in the neighborhood of the magnets. The magnetic field traps electrons and, for charge neutrality, the ion density also increases to form a high-density plasma site-isolated region within the sputter chamber 400 adjacent to the magnetron. The magnetron is usually rotated about the center of the target to achieve full coverage in sputtering of the target.

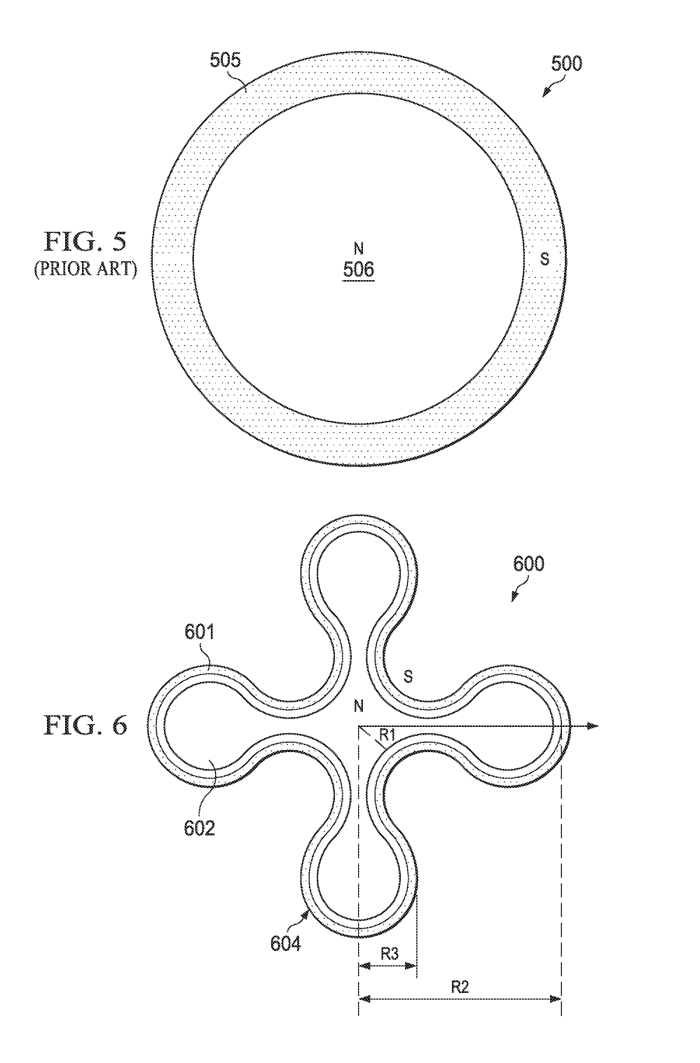

FIG. 5 is an exemplary magnetron 500 for a sputter target assembly. Magnetron 500 includes southern and northern poles 505, 506 which create a magnetic field around a sputter target. During the sputter process, a magnetic field created by magnetron 500 may be used to trap secondary electrons close to the sputter target. The electrons follow helical paths around the magnetic field lines to undergo multiple ionizing collisions, with neutral gaseous near the target, leading to a higher sputter rate.

FIG. 6 is a top view of a magnet 600. In some embodiments, magnet 600 is a magnetron 600. Magnetron 600 includes southern and northern poles 601, 602 which create a magnetic field to enhance the ionization of a plasma near the sputter target. As shown, magnetron 600 is n-fold, symmetric according to some embodiments. In some embodiments, an object has n-fold rotation symmetry (where “n” is a positive integer) when a rotation of magnitude 360/n maps the object onto itself, and no larger value of n has this property. In some embodiments, as shown in FIG. 6, magnetron 600 is four-fold symmetric as evidenced by the four lobes 604. More specifically, magnetron 600 has a quatrefoil-shape according to some embodiments of the present disclosure.

It should be understood that the present disclosure is not limited to a magnetron 600 that is four-fold symmetric or has a quatrefoil-shaped symmetry. As such, magnetron 600 may have various shapes or symmetries such that when magnetron 600 rotates, films are deposited uniformly on a substrate and the sputter target erodes uniformly. For example, magnetron 600 may be n-fold symmetric wherein “n” can be 4, 6, or 8 according to some embodiments.

In some embodiments, the size of magnetron 600 is configured for a particular size, or range of sizes, for a sputter target. For example, for a sputter target having a radius in the range of 1-2 inches, magnetron 600 may have a center radius (R1) and a maximum body length radius (R2) of approximately 1 inch and 0.5 inches, respectively and having an individual lobe radius of approximately 0.5 inches (R3). In addition, the local arc (r) of each lobe has a radian angle of 1.5 π, and the extended arc (R) has a radian angle of π, respectively, according to some embodiments. In some embodiments, the arcs 604 comprising tangent curves forming a closed loop.

It should be understood by those having ordinary skill in the art that magnetron 600 is not limited to any particular size. For example, magnetron 600 may have a size with a maximum body length diameter of 3 mm, 5 mm, 150 mm, 200 mm, 300 mm, or 450 mm.

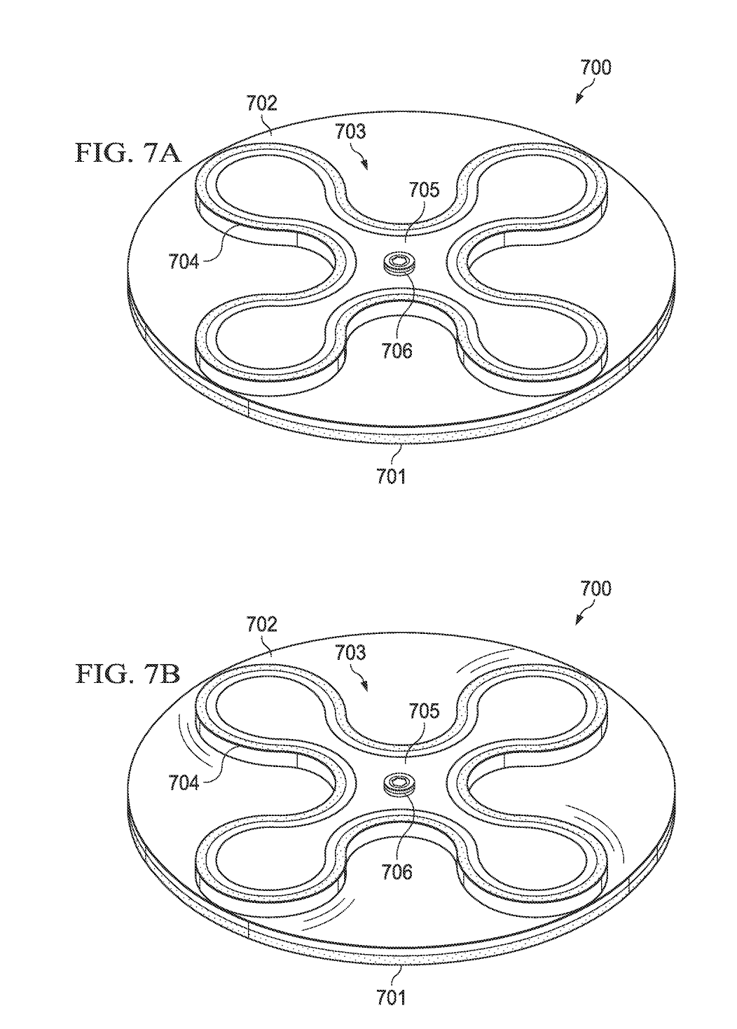

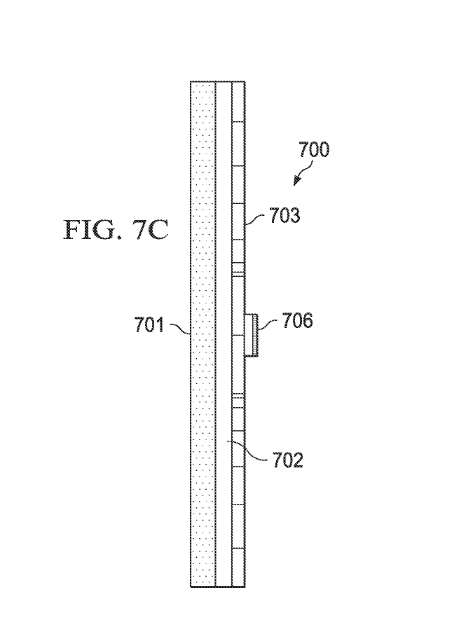

FIG. 7A is a top view of a sputter target assembly 700. Sputter target assembly 700 includes a magnetron 703 (with southern and northern poles 704, 705) having a connection to a first side of a backing plate 702. On the second side of backing plate 702 is a sputter target 701 having a connection thereto. Magnetron 703 and sputter target 701 may have a connection to backing plate 702 by various methods so long as such coupling methods enable magnetron 703 to rotate. In some embodiments, sputter target 701, backing plate 702, and magnetron 703 share a common central axis. In some embodiments, the common central axis is perpendicular to a plane of sputter target 701, backing plate 702, and magnetron 703.

In some embodiments, a fastener is used to link magnetron 703 to backing plate 702. For example, in some embodiments, a single set screw is used to link magnetron 703 to backing plate 702. There are various known set screws including, but not limited to, case point, oval point, and half-dog set screws which may be used to provide a connection for magnetron 703 and backing plate 702. In addition, according to some embodiments, a single shoulder screw or guide screw may be used to provide a connection for magnetron 703 and backing plate 702.

Further, FIG. 7A illustrates sputter target 701 having a connection to a second side of backing plate 702. Sputter target 701 provides the material for the deposited films as described above. Sputter target 701 may have a thickness in the range of 0.05 to 0.5 inches. In some embodiments, the thickness of sputter target 701 is approximately 0.5 inches. It should be understood that sputter target 701 may have various thicknesses so long as material from the sputter target 700 can be ejected therefrom to form films on a substrate with a desired thickness.

In addition, sputter target assembly 700 may include more components than shown in FIG. 7A. For example, sputter target assembly 700 may include a cooling system, such as an indirect microplate cooling system (not shown), which provides cooling to the magnetron 703.

FIG. 7B is a top view of a magnetron assembly 703 with rotational symmetry. In some embodiments, an object has rotational symmetry when there is a center point around which the object is turned (rotated) a certain number of degrees and the object looks the same. In some embodiments, as shown in FIG. 7B, magnetron assembly 703 looks the same after the assembly 703 is rotated every 90 degrees. However, the number of degrees a magnetron assembly 703 in accordance with the present disclosure is rotated for the assembly 703 to appear the same is a function of its symmetry (e.g. the value of “n” for n-fold symmetric magnetron assemblies).

FIG. 7C is a side view of a sputter target assembly 700. In particular, the figure shows a side view of sputter target 701, backing plate 702, magnetron 703, and fastener 706. It should be understood that the present disclosure is not limited to the relative thicknesses of the components shown in FIG. 7C. As such, the present disclosure is not limited to a sputter target 701 that has a thickness greater than the backing plate 702 and the magnetron 703. For example, the present disclosure is amenable to include a sputter target assembly 700 with a backing plate that has a thickness that is greater than or less than magnetron 702 and sputter target 701.

As such, because the erosion profiles 701 of sputter target systems yield a relative flat surface erosion profile, there is much more surface area for sputter gas ions to bombard relative to conventional sputter systems, thereby depositing uniform thin films onto a substrate.

As mentioned above, magnetron 703 is rotatable about backing plate 702 of the sputter target assembly 700. Magnetron 703 may rotate at a speed in the range of 1-100 rotations per minute. In some embodiments, magnetron 703 may rotate at various speeds to deposit materials upon a substrate. For example, sputter target assembly 700 may be installed within a combinatorial processing tool to deposit various materials on the surface of various site-isolated regions of a substrate.

In some embodiments, the site-isolated regions are isolated from one another. In some embodiments, the results of the films are evaluated and the characteristics of each film amongst the site-isolated regions are compared. In additions, at least one subsequent process is applied to each site-isolated region prior to or after the films are evaluated according to some embodiments. For example, after the films are formed, an etch or lithography process is applied to at least one of the films on the surface of the site-isolated regions of the substrate.

FIG. 8 illustrates one example of a pattern of site-isolated regions. In FIG. 8, the substrate 800 is still generally divided into four quadrants and within each quadrant, three site-isolated regions 801 may be processed yielding twelve site-isolated regions 801 on the substrate 800. Therefore, in this example, twelve independent experiments could be performed on a single substrate.

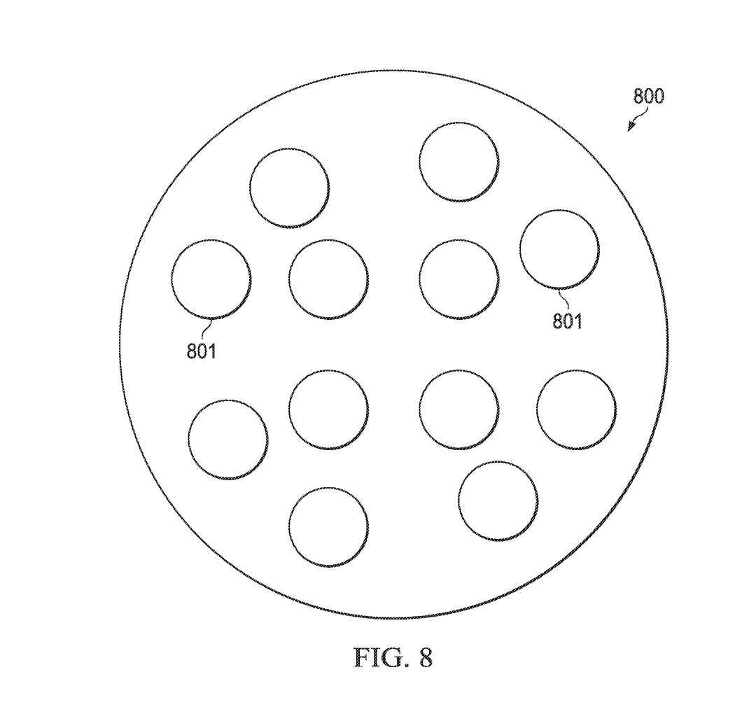

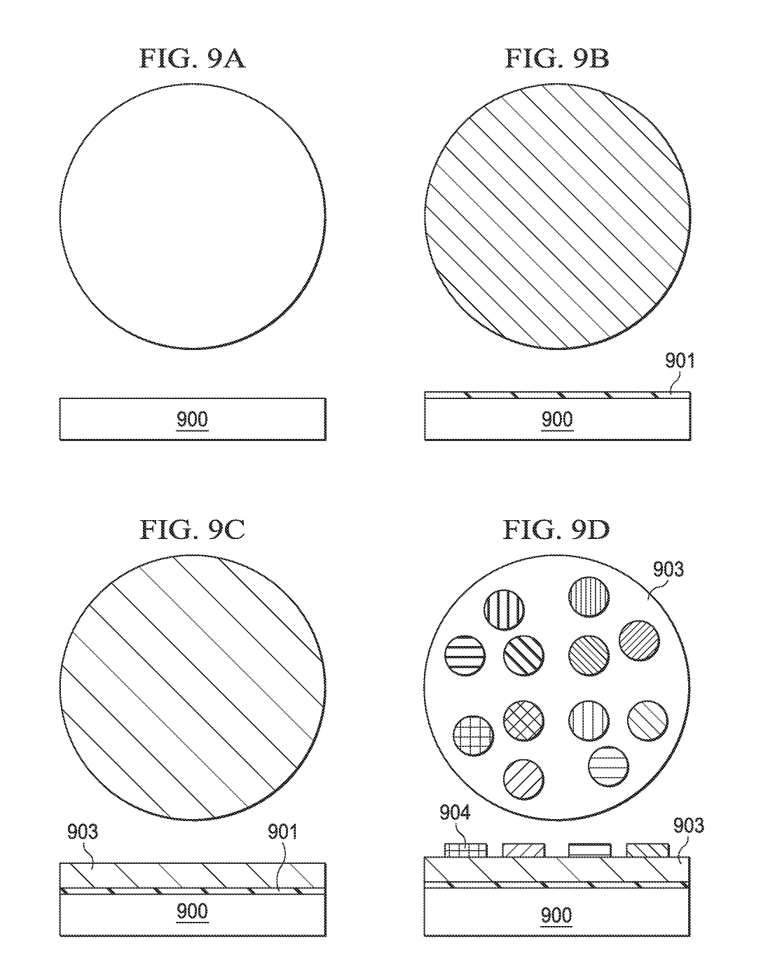

FIGS. 9A-9D illustrate an exemplary deposition sequence for forming multilayer film stacks in a combinatorial fashion. A sequence for forming a simple multilayer film stack comprising a substrate, capping layer, dielectric material, and an electrode material to form a simple capacitor stack will be used as an example. Those skilled in the art will understand that the substrate may already have several layers comprising conductive layers, dielectric layers, or both deposited thereon. FIG. 9A begins with a substrate 900 which is operable as a first electrode of a capacitor stack.

FIG. 9B illustrates a capping layer 901 disposed upon the substrate 900. In some embodiments, capping layer 901 may be formed upon substrate 900 by a physical vapor deposition process. In some embodiments, the thickness of capping layer 901 is in the range of 5-15 nanometers.

FIG. 9C illustrates a first material 903 formed above the substrate 900 and capping layer 901 wherein the first material 903 is operable as a dielectric of a capacitor stack. As illustrated in FIG. 9C, the first material 903 is uniformly formed across the substrate surface 900. This may be accomplished using a combinatorial deposition chamber having a sputter target assembly in accordance with the present disclosure therein.

In FIG. 9D, multiple alternatives of a second material 904 are formed above the first material 903 wherein the second material 904 is operable as the second electrode of the capacitor stack.

FIG. 9D illustrates twelve electrode experiments. They may represent the combinatorial variation of sputter target materials and gases, gas delivery conditions (e.g. flow rates, pressure, pulse times, etc.), electrode thickness, substrate temperature, etc. Each of the twelve capacitors would then be tested to determine the optimum material and/or processing conditions. Typical tests may comprise measuring capacitance as a function of applied voltage (i.e. C-V curve), measuring current as a function of applied voltage (i.e. I-V curve), measuring the k value of the dielectric material, measure the equivalent oxide thickness (EOT) of the dielectric material, measuring the concentration and energy levels of traps or interface states, measuring the concentration and mobility of charge carriers, etc.

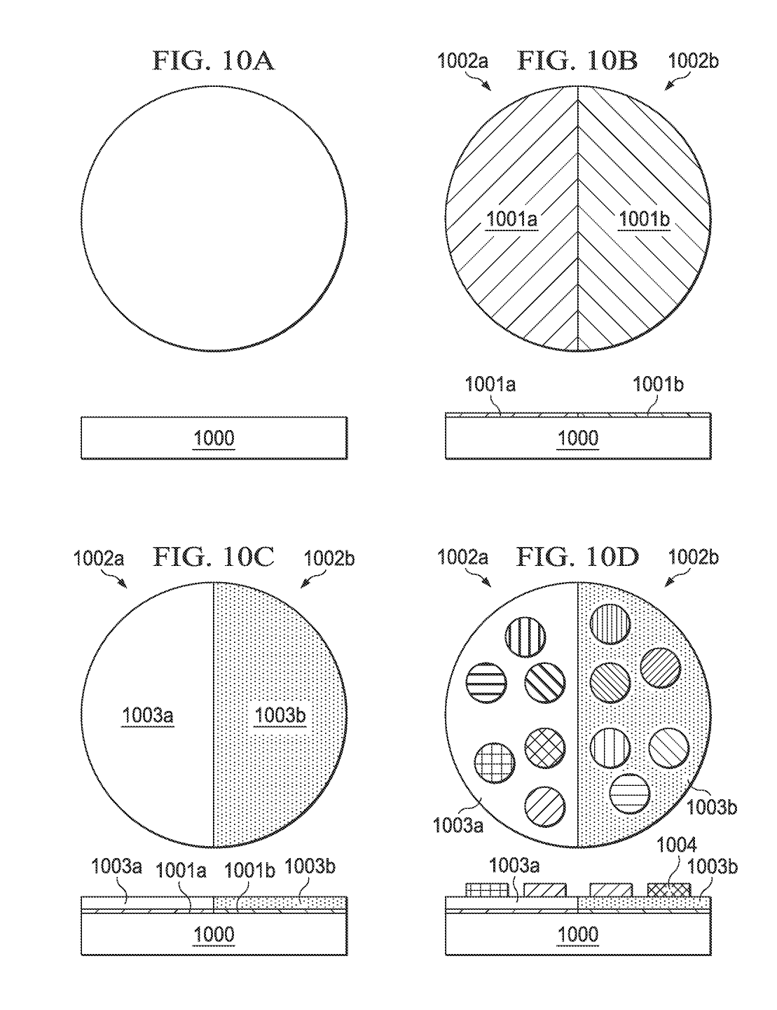

FIGS. 10A-10D illustrates an exemplary deposition sequence for forming multilayer film stacks in a combinatorial fashion. A sequence for forming a simple multilayer film stack comprising a substrate, capping layer, dielectric material, and an electrode material to form a simple capacitor stack will be used as an example. Those skilled in the art will understand that the substrate may already have several layers comprising conductive layers, dielectric layers, or both deposited thereon. FIG. 10A begins with the substrate 1000 which is operable as a first electrode of a capacitor stack.

FIG. 10B illustrates a first capping layer 1001a and a second capping layer 1001b disposed upon the substrate 1000 in two different site-isolated regions. As previously described, a first capping layer 1001a and a second capping layer 1001b may be formed upon substrate 1000 by a physical vapor deposition process. In some embodiments, the first capping layer 1001a and second capping layer 1001b are each in the range of 5-15 nanometers.

In FIG. 10C, two alternatives 1003a, 1003b of a first material are formed above the capping layers 1001a, 1001b disposed on the substrate 1000 wherein the first materials 1003a, 1003b are operable as dielectric materials of capacitor stacks. As illustrated in FIG. 10C, the two alternatives are formed in each of two sections 1002a, 1002b across the substrate surface 1000 respectively which may be accomplished using a combinatorial deposition chamber.

In FIG. 10D, multiple alternatives of a second material 1004 are formed above the first material 1003a, 1003b wherein the second material 1004 is operable as the second electrode of the capacitor stack.

FIG. 10D illustrates twelve capacitor experiments, two capping layers, two dielectric materials, and six electrode materials. They may represent the combinatorial variation of sputter target materials and gases, gas delivery conditions (e.g. flow rates, pressure, pulse times, etc.), electrode thickness, substrate temperature, etc. Each of the twelve capacitors would then be tested to determine the optimum material and/or processing conditions. Typical tests may comprise measuring capacitance as a function of applied voltage (i.e. C-V curve), measuring current as a function of applied voltage (i.e. I-V curve), measuring the k value of the dielectric material, measuring the equivalent oxide thickness (EOT) of the dielectric material, measuring the concentration and energy levels of traps or interface states, measuring the concentration and mobility of charge carriers, etc.

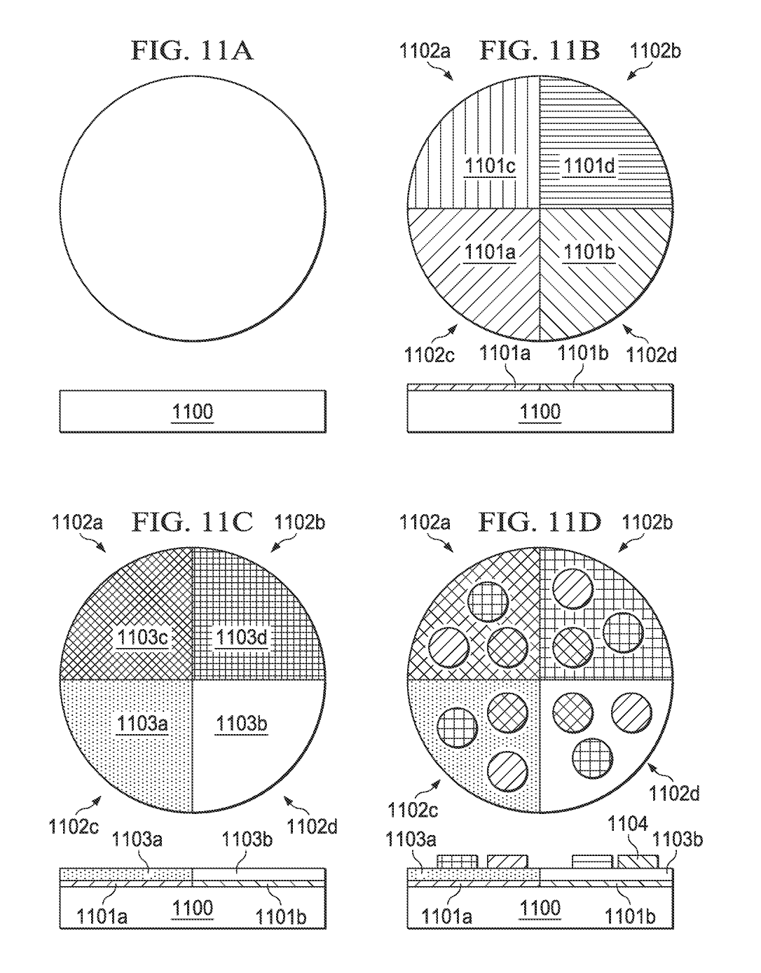

FIGS. 11A-11D illustrates an exemplary deposition sequence for forming multilayer film stacks in a combinatorial fashion. A sequence for forming a simple multilayer film stack comprising a substrate, capping layer, dielectric material, and an electrode material to form a simple capacitor stack will be used as an example. Those skilled in the art will understand that the substrate may already have several layers comprising conductive layers, dielectric layers, or both deposited thereon. FIG. 11A begins with a substrate 1100 which is operable as a first electrode of the capacitor stack.

FIG. 11B illustrates first, second, third, and fourth capping layers 1101a-1101d disposed upon the substrate 1100 in four different site-isolated regions. In some embodiments, capping layers 1101a-1101d are formed by a physical vapor deposition process. Capping layers 1101a-1101d enable various tests to determine the optimal capping material and/or processing conditions.

Moving forward, FIG. 11C illustrates four alternatives 1103a-1103d of a first material formed above the substrate 1100 wherein the first materials 1103a-1103d are operable as dielectrics a capacitor stack. As illustrated in FIG. 11C, the four alternatives are formed in each of four sections across the substrate surface respectively. This may be accomplished using a combinatorial deposition chamber having a sputter target assembly in accordance with the present disclosure therein.

In FIG. 11D, multiple alternatives of a second material are formed above the first material 1103a-1103d wherein the second material 1104 is operable as the second electrode of the capacitor stack.

FIG. 11D, illustrates twelve capacitor experiments, four capping layers, four dielectric materials and three electrode materials. They may represent the combinatorial variation of sputter target materials and gases, gas delivery conditions (e.g. flow rates, pressure, pulse times, etc.), electrode thickness, substrate temperature, etc. Each of the twelve capacitors would then be tested to determine the optimum material and/or processing conditions. Typical tests may comprise measuring capacitance as a function of applied voltage (i.e. C-V curve), measuring current as a function of applied voltage (i.e. I-V curve), measuring the k value of the dielectric material, measuring the equivalent oxide thickness (EOT) of the dielectric material, measuring the concentration and energy levels of traps or interface states, measuring the concentration and mobility of charge carriers, etc.

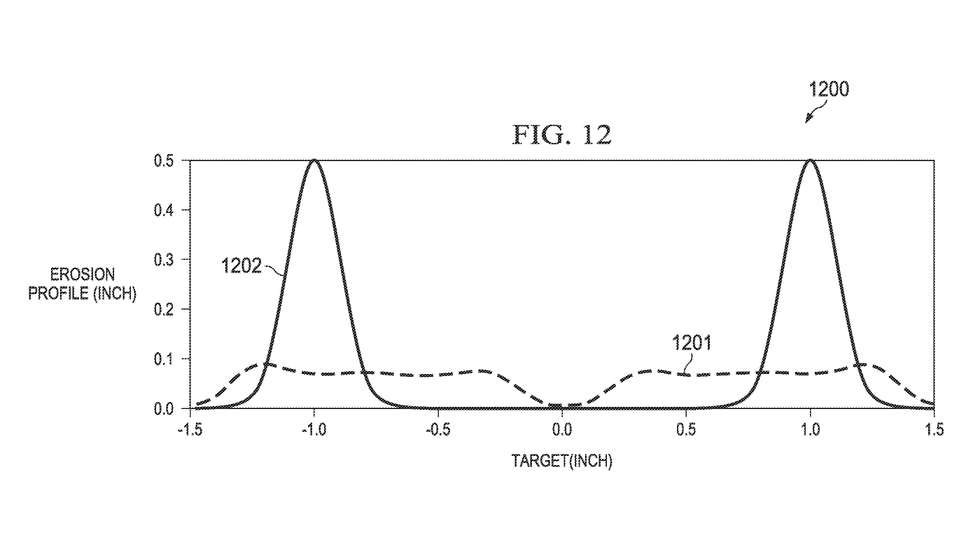

For example, FIG. 12 shows a chart 1200 with the erosion profiles 1201, 1202 sputter target system embodiments of the present disclosure. As shown, the erosion profile 1201 of sputter target systems of the present disclosure shows that the sputter target erodes uniformly resulting in a relatively flat groove erosion profile across the sputter target surface.

In some embodiments, when sputter targets exhibit uniform erosion profiles, the maximum peak surface is less than or equal to 0.1 inch of any other portion of the surface. In some embodiments, each point on the plasma track center line has a different distance to the rotation center leading to a relative flat groove erosion profile against the sputter target surface.

In contrast, the erosion profile 1202 of conventional sputter target systems include a deep groove pattern which reduces the lifetime or sputter deposition cycles of conventional sputter targets. For example, a 3 inch diameter, ½ inch thick conventional sputter target, at best, allows less than 25% sputter material usage. Accordingly, due to the deep groove erosion profile of conventional sputter target systems, most sputter targets are discarded before most of the sputter target material is consumed for deposition.

Alternatively, sputter target systems of the present disclosure may allow up to 70% sputter material usage due to the advantage gained from rotating n-fold, symmetric magnetrons. As such, sputter target systems of the present disclosure may lead to reduced sputter equipment maintenance thereby increasing sputter tool utilization.

Methods and apparatuses for combinatorial processing have been described. It will be understood that the descriptions some embodiments of the present disclosure do not limit the various alternative, modified and equivalent embodiments which may be included within the spirit and scope of the present disclosure as defined by the appended claims. Furthermore, in the detailed description above, numerous specific details are set forth to provide an understanding of various embodiments of the present disclosure. However, some embodiments of the present disclosure may be practiced without these specific details. In other instances, well known methods, procedures, and components have not been described in detail so as not to unnecessarily obscure aspects of the present embodiments.

What is claimed is:

1. A method for performing combinatorial processing, comprising:
introducing a substrate into a processing chamber wherein the processing chamber comprises a sputter target assembly disposed over the substrate wherein the sputter target assembly includes a rotatable, n-fold, symmetric-shaped magnetron and a sputter target;
depositing a first film on a surface of a first site-isolated region on the substrate;
depositing a second film on a surface of a second site-isolated region on the substrate; and
evaluating properties of the first film and the second film.

2. The method of claim 1 further comprising placing the substrate a first distance from the sputter target before depositing the first film and placing the substrate a second distance from the sputter target before depositing the second film.

3. The method of claim 1 further comprising comparing a physical or electrical characteristic of the first film and the second film.

4. The method of claim 3, wherein the characteristics of each film includes a thickness of the first and second films.

5. The method of claim 1, wherein the rotatable, n-fold, symmetric-shaped magnetron has a quatrefoil shape.

6. A substrate processing tool, comprising:
a housing defining a chamber;
a substrate support coupled to the housing and configured to support a substrate within the chamber, the substrate having a surface with a plurality of site-isolated regions and an interstitial portion surrounding each of the site-isolated regions; and
a physical vapor deposition processing unit within the housing and disposed above the substrate support comprising a sputter target assembly, wherein the sputter target assembly includes a rotatable, four-fold symmetric-shaped magnetron and a sputtering target, and wherein the physical vapor deposition processing unit is operable to deposit at least one film on the surface of each site-isolated region on the substrate.

7. The substrate processing tool of claim 6, wherein the rotatable, four-fold symmetric-shaped magnetron includes four arcs with radii of 0.5 inches and four arcs with radii of 1 inch.

8. The substrate processing tool of claim 7, wherein the rotatable, four-fold symmetric-shaped magnetron includes four additional arcs with radii of 1 inch.

9. The substrate processing tool of claim 6, wherein the rotatable, four-fold symmetric-shaped magnetron shares a common central axis with the sputtering target, wherein the common central axis is perpendicular to a plane of the rotatable, four-fold symmetric-shaped magnetron and the sputtering target, and wherein the rotatable, four-fold symmetric-shaped magnetron is rotatable around the common central axis.

10. The substrate processing tool of claim 6, wherein the rotatable, four-fold symmetric-shaped magnetron is operable to sustain the usage of the sputter target until at least sixty percent of the sputtering target has eroded.

11. A sputter target assembly, comprising:
a backing plate;
a quatrefoil-shaped magnetron disposed on a first side of the backing plate; and
a sputter target having a connection to a second side of the backing plate wherein usage of the sputter target can be sustained until at least sixty percent of the sputter target erodes.

12. The sputter target assembly of claim 11, wherein the quatrefoil-shaped magnetron is operable to achieve rotational symmetry.

13. The sputter target assembly of claim 11 further comprising an apparatus which provides cooling to the quatrefoil-shaped magnetron.

14. The sputter target assembly of claim 12, wherein a maximum body length diameter of the quatrefoil-shaped magnetron is any of 3 mm, 5 mm, 150 mm, 200 mm, 300 mm, or 450 mm.
